(19) United States
(12) Patent Application Publication
(10) Pub. No.: US 2025/0366227 A1
(43) Pub. Date: Nov. 27, 2025

(54) Single Photon Avalanche Diode

(71) Applicant: ams-OSRAM AG, Premstaetten (AT)

(72) Inventor: Georg ROEHRER, Lebring-Sankt Margarethen (AT)

(21) Appl. No.: 18/869,375

(22) PCT Filed: May 9, 2023
(86) PCT No.: PCT/EP2023/062305

§ 371 Date: Nov. 26, 2024

(30) Foreign Application Priority Data
May 27, 2022 (GB) 2207847.1

(51) Int. Cl. H10F 39/12; H10F 39/00

(52) U.S. Cl. CPC H10F 39/199; H10F 39/802; H10F 39/807; H10F 39/811

(57) ABSTRACT

A Single Photon Avalanche Diode (SPAD) sensor includes an active region including one or more active region contacts. The SPAD sensor also includes a deep isolation region along a perimeter of the SPAD sensor. The SPAD sensor further includes a contact region between the active region and the deep isolation region. The contact region includes one of more contact region contacts. The SPAD sensor additionally includes a buried well region between the contact region and active region. A size of the contact region varies along a circumference of the SPAD device.

### CROSS REFERENCE TO RELATED APPLICATION

This application is a National Stage of International Application No. PCT/EP2023/062305, filed on May 9, 2023, which designates the United States and was published in English, and which claims priority to United Kingdom Patent Application No. 2207847.1, filed on May 27, 2022, in the United Kingdom Patent and Trade Mark Office. All of the aforementioned applications are hereby incorporated by reference in their entireties.

### TECHNICAL FIELD OF THE DISCLOSURE

The present disclosure relates to Single Photon Avalanche Diode sensors and Single Photon Avalanche Diode sensor arrays, and in particular but not exclusively to 3d-stacked, backside illuminated Single Photon Avalanche Diode sensors.

### BACKGROUND OF THE DISCLOSURE

The present disclosure generally provides Single Photon Avalanche Diode (SPAD) sensors with improved photon detection efficiency (PDE) and fill factors, and/or provides a reduction to the number of required metal layers in 3D stacked SPAD wafers.

In particular, the present disclosure generally relates to 3d-stacked SPAD sensors with backside illumination (BSI) and full deep trench isolation (DTI), and/or an array of such SPAD sensor.

Several attempts have been made to enhance the PDE in SPAD devices, including the use of micro lenses, charge focusing/electrical micro lens, contact region sharing, the optimization of the depletion layer width, the use of metal mirrors, and inverse pyramid surface structures. However, many of these approaches require the addition of extra components and/or layers to the SPAD structure, complicating the manufacturing process of the device. There is therefore a need for an improved SPAD device with enhanced PDE.

It is therefore an aim of the present disclosure to provide a SPAD device with improved PDE and fill factor, and further to provide an improved SPAD array with an improved metallization layer construction.

### SUMMARY

In general, aspects of the present disclosure may provide SPAD devices and/or SPAD arrays addressing the issues described above.

According to one aspect of the present disclosure, there is provided a Single Photon Avalanche Diode (SPAD) sensor comprising:
an active region comprising one or more active region contacts;
a deep (trench) isolation region along a perimeter of the SPAD sensor;
a contact region between the active region and the deep (trench) isolation region, the contact region comprising one or more contact region contacts; and
a buried well region between the contact region and active region;
wherein a size of the contact region varies along a circumference of the SPAD device.

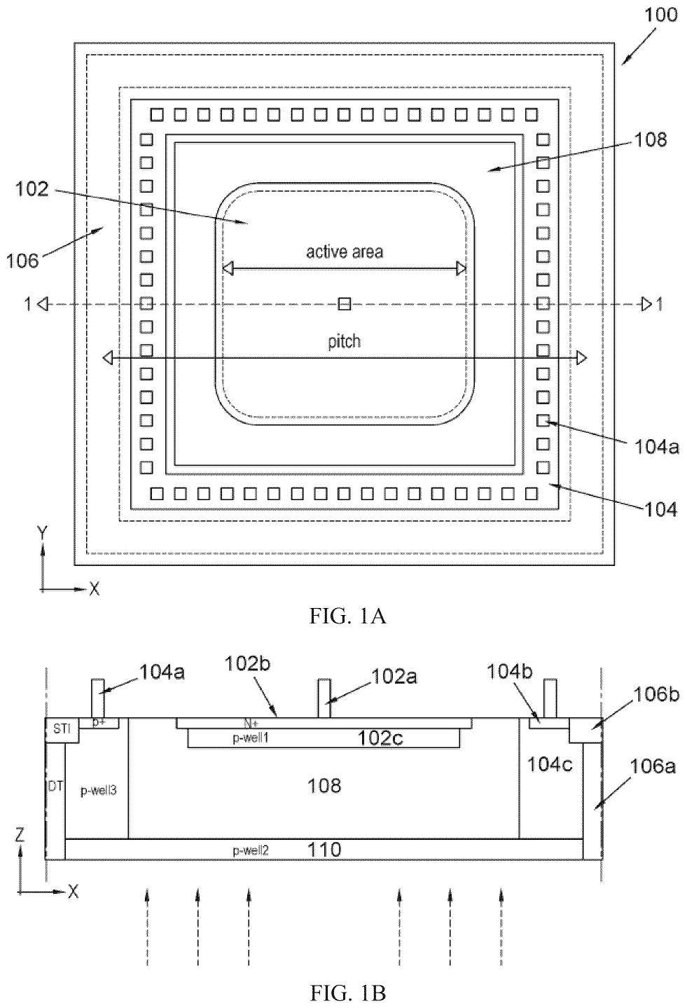

The deep (trench) isolation region may be provided around the entire perimeter of the SPAD device such that the isolation region laterally surrounds the active region. It will be understood that the phrases lateral and longitudinal are used herein to refer to relative directions. In particular, the longitudinal direction is used generally in reference to the stacking (e.g. z-direction of FIGS. 1A and 1B) of the SPAD sensor, while the lateral direction is used in reference to any direction perpendicular to the longitudinal direction (e.g. the x- and y-directions of FIGS. 1A and 1B). Thus, the phrase “laterally surrounded” may be interpreted to mean that a feature is completely encircled by another features in at least the x- and y-directions. The active region may generally comprise the doped layers of the SPAD sensor that facilitate avalanche multiplication, and may also be referred to as an avalanche multiplication region. The active area may generally refer to an area of the active region in which the avalanche multiplication occurs, as seen from a top view of the SPAD sensor.

The variable size of the contact region (also referred to as an anode ring and/or cathode ring) in the SPAD device facilitates an increase in the size of the active area compared to devices with a contact region with uniform dimensions across the circumference of the device. The improved fill factor results in an enhanced PDE. For example, SPADs with a pitch of 12.5 μm may have a PDE increase of ˜20% or more. For SPAD's with a smaller pitch, an even larger relative improvement may be achieved. It will be understood that the fill factor represents the ratio of the active area of the SPAD device (e.g. shown in FIGS. 1A and 1B by the dashed line around the edge of the active region 102) and the total area of the SPAD device. In other words, for a square SPAD device (e.g. in which the length of each side of the perimeter is equal to the pitch) the fill factor may be calculated by the following equation:

$$Fill factor = \frac{active area}{{pitch}^{2}}$$

The provision of a deep trench isolation region surrounding the SPAD device (e.g. forming a perimeter of the SPAD structure) may facilitate the isolation of the SPAD device. When a plurality of SPAD sensors are formed into an array, the deep trench isolation region may therefore further reduce cross talk between neighbouring devices. In such an array, neighbouring devices may share a single deep trench isolation region. The deep trench isolation region can be filled or partially filled with a dielectric or a metal.

Thus, a SPAD sensor according to the present disclosure may be combined with other SPAD sensors to form an array. It will be appreciated that some or all of the other SPAD sensors in such an array may also be SPAD sensors according to the present disclosure. However, this is not a requirement and in such an array the SPAD sensor of the present disclosure may be combined with one or more other SPAD sensors that do not form part of the scope of the present disclosure. Therefore, in implementations there is provided an array of SPAD sensors comprising one or more SPAD sensors according to the present disclosure.

In implementations, the SPAD device may further comprise a shallow trench isolation region along a perimeter of the SPAD sensor. As with the deep trench isolation region, the shallow trench isolation region may laterally surround the active region. The shallow trench isolation region may be located longitudinally above at least part of the deep trench isolation region, and may e.g. be in contact with the deep trench isolation region.

In implementations, the SPAD sensor is a backside illuminated SPAD sensor and/or may form a portion of a stacked 3D CMOS wafer.

Generally, the SPAD device may be provided in any shape. However, in implementations the SPAD device may comprise a plurality of corner regions and a plurality of edge regions extending between the corner regions. For example, a square SPAD device may comprise four corner regions and four edge regions extending between the corner regions. In such an implementation, a lateral size or width of the contact region may be greater at one or more of the corner regions than the lateral size of the contact region along the edge regions.

The differentiated size of the contact region in the corner region(s) and edge region(s) of the SPAD device facilitates a further proportional increases in the size of the active area, to thereby enhance the PDE of the device. Various structures fall within the scope of this implementation. For example, the contact region may be provided only in one or more of the corner regions, in some but not all of the corner regions, or in only one of the corner regions. The contact region contacts may similarly be provided only in one or more of the corner regions.

In a further example, the contact region may comprise a doped region (for contacting the contact region contacts) and a well region, where the doped region is located above the well region. The well region may be provided in only one or more of the corner regions while the doped region may extend along one or more of the edge regions.

In implementations, the active region may comprise a cathode region or electrode, and the contact region comprise an anode region or electrode (e.g. an anode ring). In other implementations, the active region comprise an anode region or electrode and the contact region comprise a cathode region or electrode (e.g. a cathode ring). As such, the active region contacts and the contact region contacts may each be provided as anode or cathode contacts.

As such, metal contact layers connected to the active region contacts and the contact region contacts may be used as anode or cathode metal connectors, depending on the implementation.

According to a further aspect of the present disclosure, there is provided a SPAD array comprising a plurality of SPAD sensors, wherein each SPAD sensor comprises one or more anode contacts and one or more cathode contacts, wherein the anode contacts are each connected to one or more anode metal connectors and the cathode contacts are each connected to one or more cathode metal connectors, and wherein
the one or more anode metal connectors and the one or more cathode metal connectors are each formed in the same metal layer.

Optionally, the SPAD arrays according to the present disclosure may comprise a central hybrid bonding region. The hybrid bonding region may comprise at least part of each of the anode metal connectors or at least part of each of the cathode metal connectors, with each of the anode or cathode metal connectors in the hybrid bonding region providing a hybrid bonding location.

At least one of the SPAD sensors in the SPAD array may be a SPAD sensor according to the present disclosure.

Advantageously, in such an array it is sufficient to use a single metal layer level for both anode metal connector and the cathode metal connector, while still enabling the routing of metal layers to a central hybrid bonding connection area. The present disclosure therefore provides a SPAD array with an improved metal layer utilization.

To facilitate this, the SPAD array may comprise one or more N×M SPAD sub-arrays, and the contact region contacts may be provided only along a perimeter of the N×M SPAD sub-arrays. Here, N and M represent the number of SPAD sensors positioned in perpendicular directions of the sub array. For example, from a top view, a 2×3 SPAD sub-array may be a rectangle sub-array with 2 SPAD sensors along a first side of the sub-array's perimeter and 3 SPAD sensors along a second side of the sub-array's perimeter, resulting in a sub-array comprising 6 SPAD sensors in total. As discussed above, in implementations the contact region contacts may form anode contacts or cathode contacts.

For example, the contact region contacts may be provided only in the corner regions along the perimeter of the N×M SPAD sub-arrays, or in only one of the corner regions along the perimeter of the N×M SPAD sub-arrays. Additionally or alternatively, in implantations the contact region contacts may be provided on one or more edge regions along the perimeter of the N×M SPAD sub-array. For example, in an array of square SPAD sensors, the sensors of the N×M sub-arrays may contact region contacts in any combination of 1, 2 and 3 corner regions and 0, 1 and 2 edge regions of the SPAD device, providing these corner and edge regions are along the perimeter of the N×M array.

In implementations, at least one of n and m may be equal to 2, such that e.g. the SPAD sub arrays are 2×M sub-arrays. For arrays of square SPAD sensors, the use of such a 2×M sub-array may assist in arranging the sub-array such that every SPAD sensor comprises at least one edge or corner region along the perimeter of the sub-array. Preferable, both N and M may be equal to 2, such that the N×M sub-arrays are 2×2 sub-arrays.

### BRIEF DESCRIPTION OF THE EMBODIMENTS

Some embodiments of the disclosure will now be described by way of example only and with reference to the accompanying drawings, in which:

FIGS. 1A and 1B schematically depict a view from above (FIG. 1A) and a cross-sectional view from the side (FIG. 1B) of an example SPAD device.

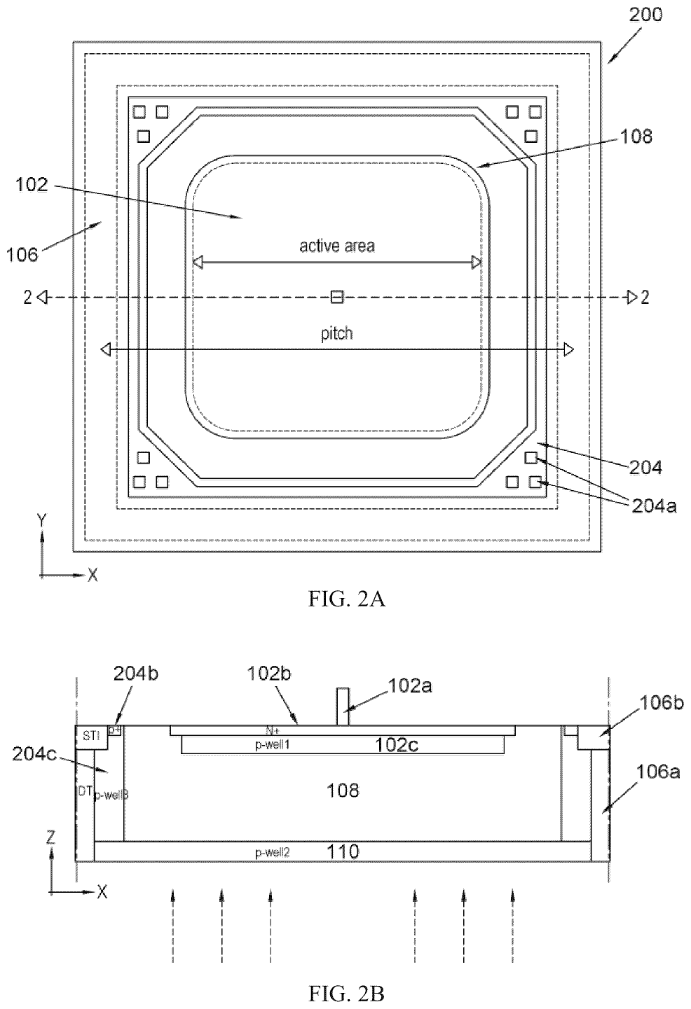

FIGS. 2A and 2B schematically depict a view from above (FIG. 2A) and a cross-sectional view from the side (FIG. 2B) of a SPAD device according to an implementation.

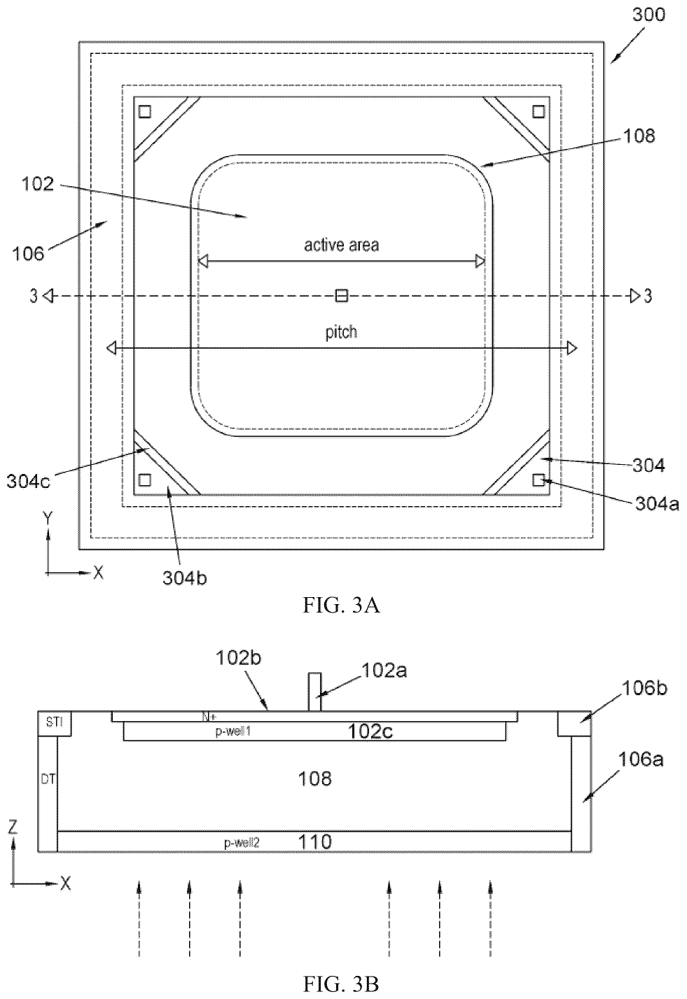

FIGS. 3A and 3B schematically depict a view from above (FIG. 3A) and a cross-sectional view from the side (FIG. 3B) of a SPAD device according to a further implementation.

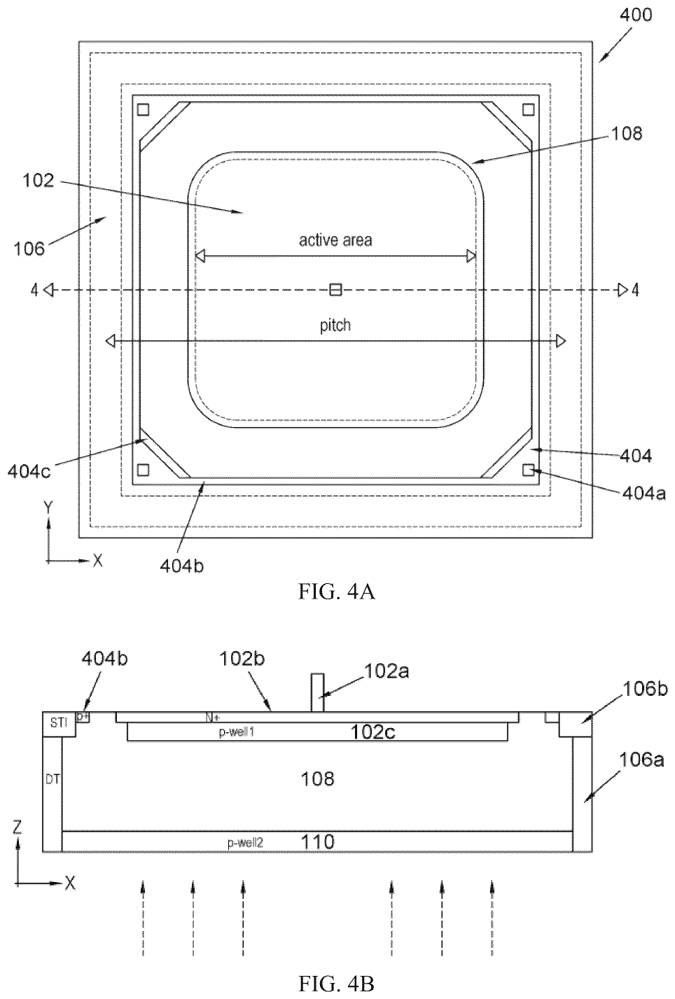

FIGS. 4A and 4B schematically depict a view from above (FIG. 4A) and a cross-sectional view from the side (FIG. 4B) of a SPAD device according to a further implementation

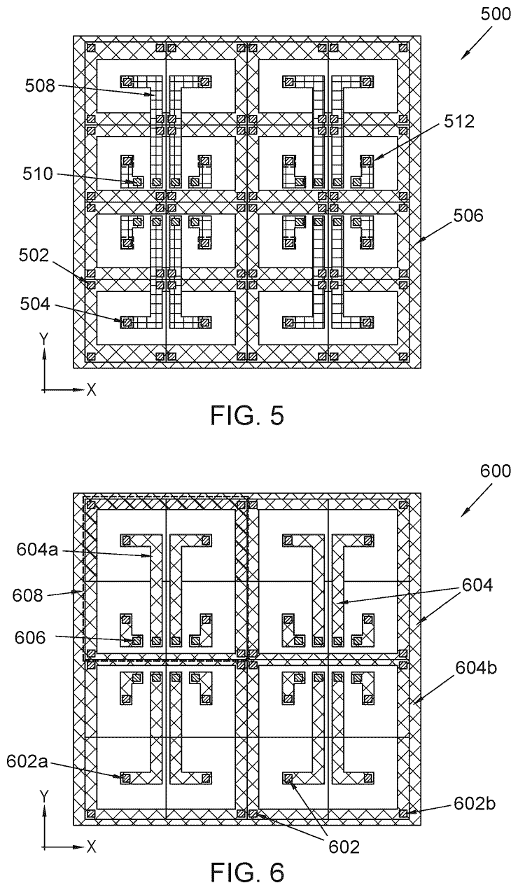

FIG. 5 schematically depicts a view from above of an example SPAD array.

FIG. 6 schematically depicts a view from above of a SPAD array according to an implementation.

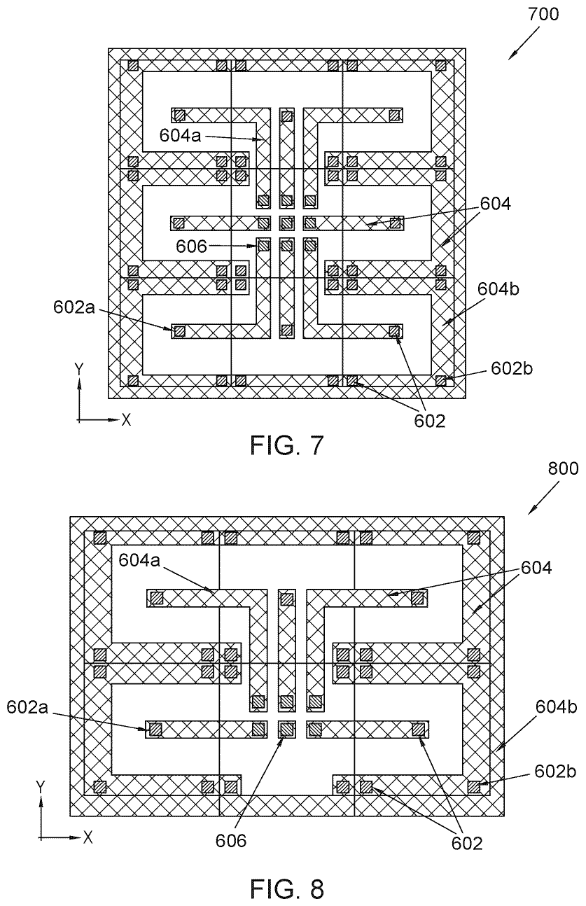

FIG. 7 schematically depicts a view from above of a 3×3 SPAD array according to an implementation.

FIG. 8 schematically depicts a view from above of a 3×2 SPAD array according to a further implementation.

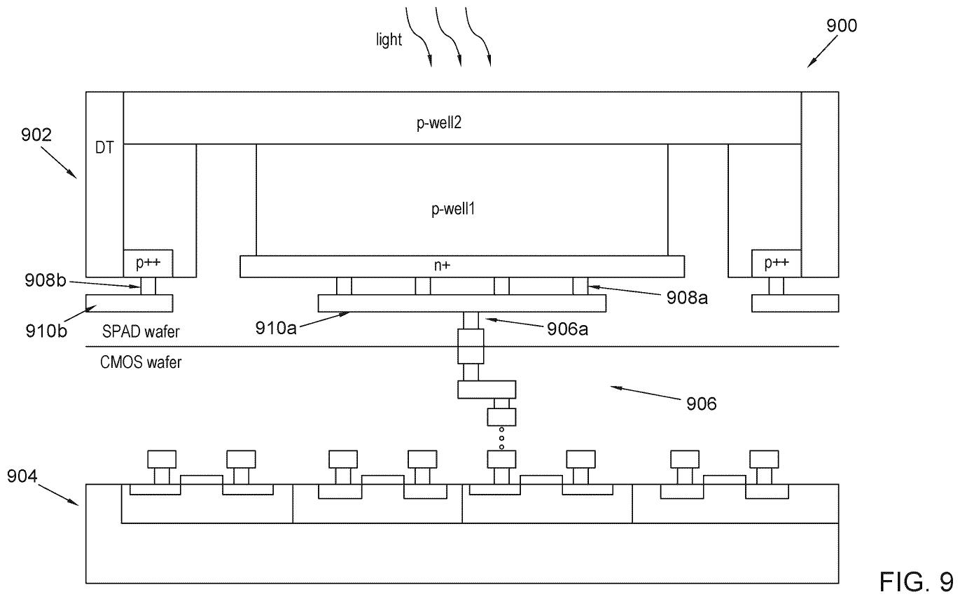

FIG. 9 schematically depicts a 3D-stacked wafer according to an implementation.

### DETAILED DESCRIPTION OF THE EMBODIMENTS

Aspects of the invention will now be described by reference to example embodiments. It will be understood that while the example embodiments below all share a similar SPAD structure, that this is merely an example structure and that the invention is not intended to be limited to only the structure shown in the example embodiments. For example, the doping shown in the examples could be reversed (e.g. n-type regions exchanged with p-type regions and vice versa) and/or the SPAD junction configuration could differ based on the intended purpose of the device. While the below examples generally describe enrichment or enhancements type SPAD devices, other known SPAD configurations including but not limited to diffused guard ring and merged implant guard ring configurations may also be implemented within the scope of the invention.

Similarly, while the SPAD structures shown below are symmetric (e.g. having an identical pitch in each of the lateral (x- and y-) directions), it is also within the scope of the disclosure for SPAD structures to be non-symmetric (e.g. having a different pitch in the lateral (x- and y-) directions). This applies equally to the active region of the SPAD device, which may also be formed into other shapes than that shown, for example an octagon or circle.

It will further be understood that the layers forming the anode and cathode regions (e.g. parts of the active region and contact region) can be different to the examples shown, and that the number of contact points in the anode and cathode regions may be different that those depicted. For example, the active region and contact region may comprise any number of contact points, as desired, such as 1, 2, 3, 4, 5 or more contacts, such as 9, 16, 25, etc. contacts. However, in some implementations fewer contacts in the active region may be preferred, as larger numbers of active region contacts may reduce the efficiency of backside illumination designs.

An example BSI SPAD device 100 is shown in FIGS. 1A and 1B. FIG. 1A schematically shows a top view and FIG. 1B schematically shows a cross-section along line 1-1 of FIG. 1A. The dashed arrows in both FIG. 1B and subsequent figures represent the path of incoming light. It will be understood that the incoming light may be incident against the SPAD device 100 from any angle. SPAD device 100 comprises an active region 102, a contact region 104, also commonly referred to as an anode or cathode ring, and an isolation region 106 comprising a deep trench isolation region 106a and a shallow trench isolation region 106b. A buried well layer or region 108, also called a deep well, is formed within the contact region 104, and may comprise a depletion region e.g. beneath and around the active region 102. In implementations, the buried well layer may be doped only with the background doping of the wafer, and the depletion region may extend until a lower doped or substrate layer such as p-well region 110. The isolation region 106 is provided around the perimeter of the SPAD device 100, to thereby isolate the SPAD device 100 from e.g. other SPAD devices forming an array of SPAD devices. This isolation may reduce a cross talk between neighbouring devices and/or a dark count rate of the SPAD device 100. SPAD device 100 may share isolation region 106 with neighbouring SPAD devices. The pitch of a SPAD device represents the repeating distance of an array of SPAD device. For example, in an array of SPAD devices the pitch may be the distance from the centre of one SPAD device to the centre of a neighbouring SPAD device. Alternatively, the pitch of a SPAD device in such an array may be e.g. the distance between the centre of the isolation region 106 on opposite sides of the device.

In this example, active region 102 comprises an n+ doped cathode region 102b and a cathode contact 102a. A doped p-well region 102c is provided on the underside of the cathode region 102b, and the avalanche breakdown occurs at and close to the border of these regions. Contact region 104 forms an anode ring with anode contacts 104a. Contact region 104 comprises a p+ doped region 104b and doped p-well region 104c. A further doped p-well region 110 forms a bottom layer or substrate of the device within the isolation region 106.

It will be understood that while this example implementation comprises an anode ring, the contact region 104 may instead form a cathode ring. Similarly, active region 102 may comprise a cathode region or an anode region. Contacts 102a and 104a may therefore more generally be referred to as an active region contact 102a and a contact region contact 104a, while cathode region 102b may be referred to as the active region contact region or a second contact region. This applies equally to all further implementations disclosed herein.

In SPAD device 100, contact region 104 has uniform dimensions around the entire circumference of the device. In other words, the width of the p+ doped region 104b and the p-well region 104c do not substantially change across the device, such that anode contacts 104a can be provided around the entire contact region 104.

As briefly discussed above, FIGS. 1A and 1B depict a known BSI SPAD 100 with a deep trench isolation region 106a which laterally surrounds the active region 102. In the SPAD device 100 of FIGS. 1A and 1B, the width of the contact region 104 is substantially uniform around the entire circumference of the device 100. This is because the width of the contact region 104 is limited by the need to be sufficient to facilitate low ohmic contact region contacts 104a around the entire perimeter of the device 100, and in that the minimum distance between the active region 102 and the contact region 104 is determined by the required lateral breakdown voltage value. This lateral breakdown voltage needs to be higher than the vertical breakdown voltage for a good SPAD with a low dark count rate, and is dependent upon the distance between the n+ and p+ regions 102b and 104b.

FIGS. 2A and 2B depict an example BSI SPAD 200. FIG. 2A schematically shows a top view and FIG. 2B schematically shows a cross-section along line 2-2 of FIG. 2A. SPAD device 200 shares a similar structure to SPAD device 100, and corresponding features are provided with the same reference numerals.

In contrast to SPAD device 100, the contact region 204 of SPAD device 200 has non uniform dimensions around the circumference of the device 200. In particular, the width of the p+ doped region 204b and the p-well region 204c are substantially greater in the corners of the device 200 than along the edges of the device 200. It will be understood that in this example implementation, the contact region 204 is an anode ring. However, in alternative implementations the contact region 204 may be a cathode ring comprising n+ doped and n-well regions in place of the p+ doped region 204b and the p-well region 204c respectively. This applies equally to all following example implementations. As depicted in FIGS. 2A and 2B, contact region 204 may therefore comprise contact region (e.g. anode) contacts 204a in the corner regions only, as the width of the contact region 204 along the edge regions may not be sufficient to facilitate low ohmic contacts along the edges of the device. However, it will be understood that SPAD device 200 need not be symmetric, and 1, 2 or 3 of the edge regions may comprise a contact region 204 that is sufficient to facilitate such contacts along these edges.

The reduced size of the contact region 204 in the edge regions of the SPAD device 200 facilitates an increase in the relative size of the active area of device 200 compared to device 100. Consequently, the improved fill factor of SPAD device 200 results in an enhanced PDE.

Advantageously, as the contact region 204 laterally surrounds the active region it is not essential that an isolation region 106 is provided in device 200, although such an isolation region 106 and in particular a deep trench isolation region 106a is still preferably provided to assist in isolating the SPAD device 200 from any neighbouring SPAD devices. For example, in some implementations the inclusion of the deep trench isolation region 106a may reduce cross talk between neighbouring devices from about 10% of a measured signal to about 2.5% or less of a measured signal. The deep trench isolation region 106a may be filled or partially filled with a dielectric material and/or a metal. Optionally, and as discussed above, the isolation region 106 may further comprise a shallow trench isolation region 106b above the deep trench isolation region 106a.

FIGS. 3A and 3B depict a further example BSI SPAD 300. FIG. 3A schematically shows a top view and FIG. 3B schematically shows a cross-section along line 3-3 of FIG. 3A. SPAD device 300 again shares a similar structure to SPAD device 100, and corresponding features are provided with the same reference numerals.

In SPAD device 300, contact region 304 comprising p+ doped region 304b and the p-well region 304c is formed only in the corner regions of the device 300, such that contact region 304 does not fully laterally surround the active region 102. Contact region 304 may therefore comprise contact region (e.g. anode) contacts 304a in the corner regions only. However, it will be understood that that SPAD device 300 need not be symmetric, and one or more corners of SPAD device 300 may not comprise the contact region 304, such that the contact region (and therefore contact region contacts 304a) are provided only in 1, 2 or 3 corners of the device. Similarly, some of the edge regions, such as 1, 2 or 3 of the edge regions, may comprise a contact region 304. The contact region 304 in these edge regions may be sufficient to facilitate contacts along these edges, or may be provided to assist in isolating the device without facilitating the use of any additional contacts.

The removal of the contact region 304 in some or all of the edge regions of the SPAD device 300 facilitates a further increase in size of the active area of device 300 compared to devices 100 and/or 200. Consequently, the improved fill factor of SPAD device 300 results in a further enhanced PDE. However, in this implementation it is particularly preferable to provide an isolation region 106 (such as at least deep trench isolation region 106a and optionally shallow trench isolation regions 106b) around the perimeter of the device 300 to reduce cross talk with, and facilitate electrical isolation between, any neighbouring devices.

FIGS. 4A and 4B depict a further example BSI SPAD 400. FIG. 4A schematically shows a top view and FIG. 4B schematically shows a cross-section along line 4-4 of FIG. 4A. SPAD device 400 again shares a similar structure to SPAD device 100, and corresponding features are provided with the same reference numerals.

In SPAD device 400, contact region 404 comprises p+ doped region 404b and the p-well region 404c. The p+ doped region 404b forms a complete ring to laterally surround the active region 102, while the p-well region 404c is provided only in the corner regions of the device 400. It will again be understood that SPAD device 400 need not be symmetric, and 1, 2 or 3 of the edge regions may comprise a contact region 404 that comprises both p+ doped region 404b and the p-well region 404c.

Advantageously, the structure of contact region 404 in SPAD device 400 facilitates an increase in the size of the active area of device 400 compared to e.g. devices 100 and 200, while also improving the isolation of SPAD device 400 compared to the device 300. Consequently, structure depicted in FIGS. 4A and 4B may provide a balance between an improved fill factor (and therefore an enhanced PDE) and a reduced dark count rate and/or cross talk between neighbouring devices.

As discussed above, the examples discussed herein are not intended to limit the scope of the invention, and alternative devices not shown are considered to be within the scope of the invention. For example, the doping shown in the examples may be reversed (e.g. n-type regions exchanged with p-type regions and vice versa) such that the contact region 204, 304, 404 forms a cathode ring rather than an anode ring. Similarly, the devices 200, 300, 400 may be formed in other shapes, such as e.g. octagons or circles. Moreover, it will be understood that features from the example SPAD sensors may be combined as desired. For example, a single device may comprise a first edge region comprising a contact region as depicted in FIGS. 2A and 2B, a second edge region edge comprising a contact region as depicted in FIGS. 3A and 3B, and a third edge region edge comprising a contact region as depicted in FIGS. 4A and 4B. Any other combination is also contemplated within the scope of the disclosure.

In particular, each example device may be provided with contact region contacts 204a, 304a, 404a in some but not all of the corner regions, such as in 1, 2 or 3 of the corner regions. Similarly, each example device may be provided with contact region contacts 204a, 304a, 404a in some but not all of the edge regions, such as in 1, 2 or 3 of the edge regions.

An example SPAD array 500 is shown in FIG. 5. The SPAD array 500 may comprise e.g. a 4×4 array of SPAD devices such as SPAD device 100 of FIGS. 1A and 1B. Each SPAD device of the array 500 comprises contact region contacts 502 electrically connected to a shared first metal layer 506 (shown with crossed diagonal hatching), while the second metal layers 508 (shown with vertical/horizontal hatching) are electrically connected to the first metal layer via a via 512 (shown here as a dashed square surrounding each of the active region contacts 504). Each metal connecting or connector portion of the second metal layer 508 comprises a hybrid contact bonding site 510 (shown with leftwards diagonal hatching). The contact region contacts 502 and active region contacts 504 are both shown with rightward diagonal hatching. While the contact region contacts 502 are shown in the corners of each SPAD device, they may more generally be provided around the entire perimeter of each device, as shown in FIGS. 1A and 1B. The active region contacts 504, meanwhile, are provided in the active area (i.e. approximately centrally) within each SPAD device.

Such 4×4 arrays may form a subset of a larger array (e.g. 320×240). The 4×4 array may be replicated to achieve the required total array size. In such an array, every SPAD cathode needs to be connected to a quenching circuit, which forms part of the complementary metal-oxide-semiconductor (CMOS) circuits on the 3d-stacked CMOS wafer. The CMOS core voltage for advanced CMOS nodes is typically small (e.g. around 0.9V), and therefore, for the quenching circuit, IO transistors capable of withstanding a higher voltage (e.g. around 3.3V) are used in order to allow for a high excess bias voltage (e.g. around 3.0V). As a result, typically a large spacing between the CMOS core and the quenching circuit IO transistors is required because of the different voltage domains.

Hence, it is beneficial that the quenching circuits for several SPADs in a SPAD array are located close or next to each other. Those clusters of SPADs may also share CMOS circuitry such as time to digital converters (TDC) and histogram memories. SPAD array 500 of FIG. 5 therefore provides the hybrid bonding locations for all 16 SPADs of the 4×4 array in a localized area. To achieve this, the first 506 and second 508 metal layers overlap, and must therefore be provided as separate layers within the 3D stacked SPAD wafer of the SPAD array 500.

In contrast, if the hybrid bonding sites were placed within the SPAD pitch of each SPAD device, the use of one or more metallization layers of the CMOS wafer would be limited. This in turn would significantly constrain the CMOS wafer.

In some cases, it is desirable to combine SPAD devices into arrays comprising multiple SPAD devices. One such example 4×4 SPAD array 500 is depicted in FIG. 5. As discussed above, the SPAD array 500 comprises overlapping the first 506 and second 508 metal layers, which are therefore provided as separate layers within the 3D stacked SPAD wafer of the SPAD array 500.

FIG. 6 depicts a top view of a 4×4 SPAD array 600. SPAD array 600 may comprise one or more SPAD devices such as those depicted in FIGS. 2, 3 and 4, or any other suitable SPAD device. As with array 500, the 4×4 array 600 may form a subset of a larger array (e.g. 320×240), and the 4×4 array 600 may be replicated to achieve the required total array size. The colour coding of FIG. 6 is the same as that of FIG. 5, with rightward diagonal hatching, crossed diagonal hatchings and leftward diagonal hatching representing the anode/cathode contacts 602, first metal layer 604 and hybrid bonding sites 606 respectively.

In SPAD array 600, each SPAD device comprises active region contacts 602a connected to an active region metal connector (also called a hybrid bonding metal connector) 604a, and contact region contacts 602b connected to a contact region metal connector 604b. Active region metal connector 604a and contact region metal connector 604b may also be referred to as anode and cathode metal connectors. It will be understood that the either region 604a and 604b may form the anode or cathode connectors, depending on the construction of the SPAD devices (e.g. the doping of the layers).

In array 600, each SPAD device comprises contact region contacts 602b in only a single corner region. In this way, contact region metal connector 604b does not need to be provided around the perimeter of every SPAD device in the array 600, and it is sufficient to use a single metal layer level for both hybrid bonding metal connector 604a and contact region metal connector 604b, while still enabling the routing of the hybrid bonding metal connectors 604a to a central hybrid bonding connection area comprising hybrid bonding sites 606. Array 600 therefore provides a 3D stacked SPAD wafer structure with an improved metal layer utilization.

It will be understood that the structure of array 600 is not limited to use with SPAD devices comprising contact region contacts in only a single corner region, and that SPAD devices with contact region contacts in 2 corner regions, 3 corner regions or 4 corner regions of the SPAD device may also be utilised. Similarly, such an array structure may also be implemented with SPAD devices comprising contact region contacts along 1, 2 or 3 edge regions, or any combination of 1, 2, 3 and 4 corner regions and 0, 1, 2 and 3 edge regions of the SPAD device.

In implementations, a SPAD array may comprise a plurality of N×M sub-arrays, where N and M are integers. For example, the 4×4 array 600 shown in FIG. 6 comprises multiple example 2×2 sub-arrays 608, with N representing the number of SPAD sensors in a first (e.g. y) direction and M representing the number of SPAD sensors in a second (e.g. x) direction. It will be understood that N and M may be other integer values and/or and may each be different integer values, and that a sub-array such as the 2×2 sub-array 608 may be utilised as an independent 2×2 array. Similarly, larger arrays that may themselves comprise sub-arrays (such as 4×4 array 600) may also form sub-arrays of larger arrangements. For example, as discussed above the 4×4 array 600 may form a subset of a larger e.g. 320×240 array, and the 4×4 array 600 may be replicated or combined with other suitable (sub-) arrays to achieve the required total array size. The sub-array(s) may therefore generally represent the smallest repeatable pattern(s) of SPAD sensors used to form a particular implementation of the SPAD array.

Further example arrays are shown in FIGS. 7 and 8. FIG. 7 depicts a top view of an example 3×3 SPAD array 700, while FIG. 8 depicts an example 3×2 SPAD array 800. In both cases, the features corresponding to the features of array 600 are provided with like reference numerals.

In both array 700 and array 800, the array structure enables the use of a single metal layer 604 level for both hybrid bonding metal connector 604a and contact region metal connector 604b, while still enabling the routing of the hybrid bonding metal connectors 604a to a central hybrid bonding connection area comprising hybrid bonding sites 606. As with array 600, arrays 700 and 800 therefore provide a 3D stacked SPAD wafer structure with an improved metal layer utilization.

In some implementations, the contact region contacts 602b may only be provided along the perimeter of the array and/or along the perimeter of the N×M sub-arrays. For example, in FIG. 6 the contact region contacts 602b are provided only along the perimeters of the 2×2 sub-arrays 608. As such, while an array and/or sub-array may comprise any number of SPAD devices, preferably the array (or the sub-arrays forming a larger array) are N×M arrays, with at least one of N and M equal to 1 or 2, such that all SPAD sensors in the array include at least one corner or edge region along the perimeter of a sub-array.

It will be understood that more generally, the SPAD sub-array or array be take any shape formed by the SPAD sensors, including non-symmetric shapes that cannot be described using the format of a N×M grid.

FIG. 9 depicts an example 3D-stacked CMOS wafer 900. The 3D stacked wafer 900 comprises a SPAD sensor 902 and CMOS wafer layers 904 forming part of a CMOS circuit. The SPAD sensor 902 and CMOS circuit are connected via hybrid bonding 906, which comprises a hybrid bonding region or contact 906a, such as the hybrid bonding regions 606 depicted in FIGS. 6-8. The 3D stacked CMOS wafer 900 further comprises an active region metal connector 910a and contact region metal connector 910b formed from a single metal layer, which are respectively connected to the SPAD sensor 902 by active and contact region contacts 908a, b.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

List of Reference Numerals

| | |
|---|---|
| 100 | SPAD sensor; |
| 102 | Active region; |
| 102a | Active region contact; |
| 102b | Cathode region; |
| 102c | Well region; |
| 104 | Contact region; |
| 104a | Contact region contact; |
| 104b | Doped region; |
| 104c | Well region; |
| 106 | Isolation region; |
| 106a | Deep trench isolation region; |
| 106b | Shallow trench isolation region; |
| 108 | Buried well layer; |
| 110 | Well region; |
| 200 | SPAD sensor; |
| 204 | Contact region; |
| 204a | Contact region contact; |
| 204b | Doped region; |
| 204c | Well region; |
| 300 | SPAD sensor; |
| 304 | Contact region; |
| 304a | Contact region contact; |
| 304b | Doped region; |
| 304c | Well region; |
| 400 | SPAD sensor; |
| 404 | Contact region; |
| 404a | Contact region contact; |
| 404b | Doped region; |
| 404c | Well region; |
| 500 | SPAD array; |
| 502 | Contact region contact; |
| 504 | Active region contact; |
| 506 | First metal layer; |
| 508 | Second metal layer; |
| 510 | Hybrid bonding site; |
| 600 | SPAD array; |
| 602 | Anode/Cathode contacts; |
| 602a | Active region contact; |
| 602b | Contact region contact; |
| 604 | Metal layer; |
| 604a | Active region metal connector; |
| 604b | Contact region metal connector; |
| 606 | Hybrid bonding site; |
| 608 | SPAD sub-array; |
| 700 | SPAD array; |
| 800 | SPAD array |
| 900 | 3D-stacked wafer; |
| 902 | SPAD sensor; |
| 904 | CMOS wafer layers; |
| 906 | Hybrid bonding; |
| 906a | Hybrid bonding contact; |
| 908a | Active region contact; |
| 908b | Contact region contact; |
| 910a | Active region metal connector; and |
| 910b | Contact region metal connector. |

1. A Single Photon Avalanche Diode (SPAD) sensor comprising:
an active region comprising one or more active region contacts;
a deep isolation region along a perimeter of the SPAD sensor;
a contact region between the active region and the deep isolation region, the contact region comprising one or more contact region contacts; and
a buried well region between the contact region and active region;
wherein a size of the contact region varies along a circumference of the SPAD device.

2. The SPAD sensor of claim 1, wherein the SPAD sensor is a backside illumination SPAD sensor.

3. The SPAD sensor of claim 1, further comprising a shallow isolation region along the perimeter of SPAD sensor, and optionally wherein the shallow isolation region is located above the deep isolation region.

4. The SPAD sensor of claim 1, wherein the SPAD device comprises a plurality of corner regions and a plurality of edge regions extending between the corner regions; and
wherein the size of the contact region is greater at one or more of the corner regions than the size of the contact region along the edge regions.

5. The SPAD sensor of claim 4, wherein the contact region comprises a well region and a doped region above the well region, wherein the one or more contact region contacts are in electrical contact with the doped region; and wherein the well region is located in only one or more of the corner regions and the doped region extends along the edge regions.

6. The SPAD sensor of claim 4, wherein the contact region is located in only one or more of the corner regions, optionally wherein the contact region is located in some but not all of the corner regions, and further optionally wherein the contact region is provided in only one of the corner regions.

7. The SPAD sensor of claim 4, wherein the contact region contacts are located only in one or more of the corner regions.

8. The SPAD sensor of claim 1, wherein the active region comprises a cathode region and the contact region comprises an anode region.

9. The SPAD sensor of claim 1, wherein the active region comprises an anode region and the contact region comprises a cathode region.

10. A Single Photon Avalanche Diode (SPAD) array comprising:
a plurality of SPAD sensors, wherein each SPAD sensor comprises one or more anode contacts and one or more cathode contacts, wherein the anode contacts are each connected to one or more anode metal connectors and the cathode contacts are each connected to one or more cathode metal connectors, and
a hybrid bonding region, wherein the hybrid bonding region comprises at least part of each of the anode metal connectors or at least part of each of the cathode metal connectors; and
wherein the one or more anode metal connectors and the one or more cathode metal connectors are each formed in the same metal layer.

11. A SPAD array according to claim 10, wherein at least one of the SPAD sensors is a SPAD sensor comprising:
an active region comprising one or more active region contacts;
a deep isolation region along a perimeter of the SPAD sensor;
a contact region between the active region and the deep isolation region, the contact region comprising one or more contact region contacts; and
a buried well region between the contact region and active region;
wherein a size of the contact region varies along a circumference of the SPAD device.

12. The SPAD array of claim 10, wherein the SPAD array comprises one or more N×M SPAD sub-arrays, wherein N and M are integers representing the number of SPAD sensors along a lateral and longitudinal axis of the SPAD sub-array, and
wherein the one or more anode contacts or the one or more cathode contacts are located only along a perimeter of the N×M SPAD sub-arrays; and
optionally wherein one or both of N and M are equal to or less than 2.

13. The SPAD array of claim 10, wherein the one or more anode contacts or the one or more cathode contacts are located only in the corner regions of each SPAD sensor, and optionally wherein the one or more anode contacts or the one or more cathode contacts are provided in only one corner region of each SPAD sensor.

14. The SPAD array according to claim 11, wherein the deep isolation region is shared between adjacent SPAD sensors.

15. A three dimensional (3D) stacked wafer comprising one or more SPAD sensors according to claim 1.

16. A three dimensional (3D) stacked wafer comprising a SPAD array according to claim 10, wherein the 3D stacked wafer is a 3D stacked complementary metal-oxide-semiconductor (CMOS) wafer.
